(19) United States
(12) Patent Application Publication
(10) Pub. No.: US 2024/0288785 A1
(43) Pub. Date: Aug. 29, 2024

(54) CLEANING COMPOSITION AND METHOD OF CLEANING MASK BY USING THE SAME

(71) Applicant: Samsung Electronics Co., Ltd., Suwon-si (KR)

(72) Inventors: Jungah KIM, Suwon-si (KR); Jimin CHUN, Iksan-si (KR); Hyojoong YOON, Iksan-si (KR); Yonghwan CHO, Iksan-si (KR); Junyoul CHOI, Suwon-si (KR); Sangwon BAE, Suwon-si (KR)

(73) Assignees: Samsung Electronics Co., Ltd., Suwon-si (KR); DONGWOO FINE-CHEM CO., LTD., Iksan-si (KR)

(21) Appl. No.: 18/585,900

(22) Filed: Feb. 23, 2024

(30) Foreign Application Priority Data
Feb. 28, 2023 (KR) 10-2023-0026910

(51) Int. Cl. G03F 7/00; C11D 7/08; C11D 7/10; C11D 7/26; G03F 1/22

(52) U.S. Cl. CPC G03F 7/70925; C11D 7/08; C11D 7/105; C11D 7/265; G03F 1/22; G03F 7/70033

(57) ABSTRACT

Described is a cleaning composition including an inorganic acid or salt thereof and an organic acid, wherein the organic acid has a first acid dissociation constant (PKa₁) and a second acid dissociation constant (PKa₂). PKa₁ is less than PKa₂, and PKa₁ is from about 1 to about 3, and PKa₂ is from about 4 to about 7.

### CROSS-REFERENCE TO RELATED APPLICATION

This application is based on and claims priority under 35 U.S.C. § 119 to Korean Patent Application No. 10-2023-0026910, filed on Feb. 28, 2023, in the Korean Intellectual Property Office, the disclosure of which is incorporated by reference herein in its entirety.

### BACKGROUND

Some inventive concepts relate to a cleaning composition and a method of cleaning a mask by using the cleaning composition. Some example embodiments of the inventive concepts relate to a cleaning composition including, for example, an inorganic acid or salt thereof and an organic acid, and a method of cleaning a mask using the cleaning composition.

With the development of the electronic industry and increased consumer's demand for electronic products, semiconductor elements have become highly integrated and miniaturized. According to this trend, in order to form a fine pattern in a semiconductor element, extreme ultraviolet (EUV) light has been used in a lithography process for forming the pattern. When a lithography process using EUV light is performed, a EUV mask used in the lithography process may be contaminated by unwanted substances, such as, for example, tin and/or tin oxide generated, for example, during the lithography process. Accordingly, physical cleaning of the EUV mask may be performed, for example based on a scanning electron microscope (SEM) analysis, to remove unwanted substances, for example tin and/or tin oxide, formed on the EUV mask. However, the physical cleaning has a limitation in removing, for example, tin and/or tin oxide from the EUV mask pattern, the removing being difficult to analyze by SEM, and the physical cleaning taking a lot of time. Accordingly, there is a need for a cleaning composition, and corresponding method using the cleaning composition, for quickly cleaning a EUV mask by effectively removing unwanted substances including, for example, tin and/or tin oxide, formed on the EUV mask and without damaging the EUV mask.

### SUMMARY

Inventive concepts provide a cleaning composition for quickly cleaning a EUV mask without damaging the EUV mask when removing, for example, tin or tin-containing contaminants formed on the EUV mask, and a method of cleaning a mask by using the same.

According to some example embodiments, a cleaning composition includes an inorganic acid or salt thereof and an organic acid, wherein the organic acid has a first acid dissociation constant (PKa₁) and a second acid dissociation constant (PKa₂), PKa₁ is less than PKa₂, PKa₁ is from about 1 to about 3, and PKa₂ is from about 4 to about 7.

According to some example embodiments, a cleaning composition includes an inorganic acid or salt thereof, an organic acid, and deionized water, wherein the organic acid has a first acid dissociation constant (Pka₁) and a second acid dissociation constant (Pka₂), PKa₁ is less than PKa₂, PKa₁ is from about 1 to about 3, PKa₂ is from about 4 to about 7, and the inorganic acid is sulfuric acid or nitric acid.

According to some example embodiments, a method of cleaning a mask includes providing an extreme ultraviolet (EUV) mask used in a EUV lithography process, and cleaning, by using a cleaning composition, tin or tin oxide formed on the EUV mask in the EUV lithography process, wherein the cleaning composition includes an inorganic acid or salt thereof and an organic acid, the organic acid has a first acid dissociation constant (PKa₁) and a second acid dissociation constant (PKa₂), PKa₁ is less than PKa₂, PKa₁ is from about 1 to about 3, PKa₂ is from about 4 to about 7,in the cleaning, the inorganic acid or salt thereof combines with the tin and allows the tin to be soluble in water, and, in the cleaning, the organic acid chelates with the tin oxide and forms a chelate compound with tin of the tin oxide.

### BRIEF DESCRIPTION OF THE DRAWINGS

Example embodiments of some inventive concepts will be more clearly understood from the following detailed description taken in conjunction with the accompanying drawings in which:

FIG. 1 is a flowchart of a method of cleaning a mask, according to an example embodiment;

FIGS. 2A to 2C are cross-sectional views showing each operation of a method of cleaning a mask, according to an example embodiment;

FIGS. 3A to 3G are cross-sectional views showing each operation of a method of cleaning a substrate, according to an example embodiment; and

FIGS. 4A and 4B are schematic diagrams illustrating extreme ultraviolet (EUV) exposure performed on a photoresist layer on a feature layer.

### DETAILED DESCRIPTION OF EXAMPLE EMBODIMENTS

Hereinafter, example embodiments of some inventive concepts are described in detail with reference to the accompanying drawings. The same reference numerals are used for the same elements in the drawings, and redundant descriptions thereof are omitted.

Expressions such as “at least one of,” when preceding a list or group of elements, modify the entire list or group of elements and do not modify the individual elements of the list or group. For example, “at least one of A, B, and C,” and similar language (e.g., “at least one selected from the group consisting of A, B, and C”), may be construed as A only, B only, C only, or any combination of two or more of A, B, and C, such as, for instance, ABC, AB, BC, and AC.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

A cleaning composition according to an example embodiment may include an inorganic acid or salt thereof and an organic acid. During an extreme ultraviolet (EUV) lithography process, the inorganic acid or salt thereof may combine with tin formed on the EUV mask to make the tin soluble in water. The organic acid may form, through a chelation reaction with tin oxide formed on the EUV mask during the EUV lithography process, a chelate compound with tin of the tin oxide form through a chelation reaction.

In an example embodiment, the inorganic acid or salt thereof may include at least one selected from a group consisting of nitric acid or salt thereof and sulfuric acid or salt thereof. For example, the inorganic acid may include either nitric acid or salt thereof, or sulfuric acid or salt thereof, or, for example, the inorganic or salt thereof may include both nitric acid or salt thereof and sulfuric acid or salt thereof.

In some example embodiments, the salt of the inorganic acid may include at least one selected from the group consisting of ammonium, sodium, magnesium, guanidine, and potassium salts of the inorganic acid. For example, the salt of the inorganic acid may include at least one selected from the group consisting of ammonium nitrate, guanidine nitrate, sodium nitrate, magnesium nitrate, potassium nitrate, ammonium sulfate, sodium sulfate, potassium sulfate, magnesium sulfate, potassium hydrogen sulfate, sodium hydrogen sulfate, and ammonium hydrogen sulfate.

In an example embodiment, the inorganic acid may not contain a halogen element. For example, the inorganic acid may not include hydrofluoric acid, hydrochloric acid, bromic acid, and iodic acid. When the inorganic acid includes a halogen element, the inorganic acid containing the halogen element may damage the EUV mask, by damaging, for example, ruthenium, tantalum, quartz, chromium, and/or other materials constituting, for example, the layers (for example, functional layers) and/or other features (for example, fiducials, alignment marks, identification marks, and protective coatings) included in the EUV mask, but examples are not limited thereto.

In an example embodiment, the inorganic acid may not include phosphoric acid. When the inorganic acid includes phosphoric acid, a removal rate of, for example, tin on the EUV mask by the cleaning composition is reduced, and thus, for example, tin removal may not be effectively performed.

In an example embodiment, content of the inorganic acid or salt thereof may be about 1 wt % to about 30 wt % based on a total weight of the cleaning composition. For example, the content of the inorganic acid or salt thereof may be about 1 wt % to about 30 wt %, about 3 wt % to about 30 wt %, about 5 wt % to about 25 wt %, about 5 wt % to about 20 wt %, or about 10 wt % to about 20 wt % based on the total weight of the cleaning composition.

In an example embodiment, the organic acid has a first acid dissociation constant (PKa₁) and a second acid dissociation constant (PKa₂), and a value of the first acid dissociation constant may be less than a value of the second acid dissociation constant.

In an example embodiment, the value of the first acid dissociation constant of the organic acid may be about 1 to about 4, and the value of the second acid dissociation constant of the organic acid may be about 4 to about 8. For example, the value of the first acid dissociation constant (PKa₁) of the organic acid is from about 1 to about 4, or from about 1 to about 3, and the value of the second acid dissociation constant (PKa₂) of the organic acid is from about 4 to about 8, or from about 4 to about 7. The lower the value of the first acid dissociation constant of the organic acid, the better the organic acid provides hydrogen ions, and the hydrogen ions provided from the organic acid chelate with tin oxide formed on the EUV mask to form a chelate compound with tin of the tin oxide. In addition, when the value of the second acid dissociation constant is greater than the value of the first acid dissociation constant, because the possibility of re-ionization of the hydrogen ions forming the chelate compound with tin of the tin oxide is low, the tin oxide may be removed more effectively.

In an example embodiment, the organic acid may include two or more acidic groups. For example, the organic acid may include two or more carboxyl groups.

In an example embodiment, the organic acid may include two or more carboxyl groups. For example, the organic acid may be a dicarboxylic acid containing two carboxyl groups.

In an example embodiment, the organic acid may be one selected from the group consisting of oxalic acid, maleic acid, malonic acid, succinic acid, citric acid, fumaric acid, glutaric acid, and methylmalonic acid. For example, the organic acid may be selected from the group consisting of oxalic acid, maleic acid, and malonic acid.

In an embodiment, the organic acid may not include a peroxide group. When the organic acid includes peroxide, the organic acid including the peroxide group may damage the EUV mask, for example, by damaging ruthenium and the like included in the layers included in the EUV mask, and/or by damaging various features of the EUV mask.

In an example embodiment, the content of the organic acid may be about 0.01 wt % to about 1.5 wt % based on the total weight of the cleaning composition. For example, the content of the organic acid may be about 0.01 wt % to about 1.5 wt %, about 0.01 wt % to about 1 wt %, about 0.1 wt % to about 0.7 wt %, or about 0.1 wt % to about 0.5 wt % based on the total weight of the cleaning composition.

In an example embodiment, a ratio of the content of the organic acid in the cleaning composition to the content of the inorganic acid or salt thereof in the cleaning composition may be about 1:1 to about 1:60. For example, the ratio of the content of the organic acid included in the cleaning composition to the content of the inorganic acid or salt thereof included in the cleaning composition is about 1:1 to about 1:60, about 1:5 to about 1:60, about 1:5 to about 1:30, about 1:5 to about 1:20, or about 1:10 to about 1:20. When the ratio of the content of the organic acid included in the cleaning composition to the content of the inorganic acid or salt thereof included in the cleaning composition is higher than 1:1, tin, for example, formed on the EUV mask may not be effectively removed by the cleaning composition. When the ratio of the content of the organic acid included in the cleaning composition to the content of the inorganic acid or salt thereof included in the cleaning composition is lower than 1:60, tin oxide, for example, formed on the EUV mask may not be effectively removed by the cleaning composition.

In an example embodiment, the cleaning composition may not include a surfactant. The surfactant may be adsorbed on the surface of tin and/or tin oxide formed on the EUV mask, and tin and/or tin oxide on the surface of which the surfactant is adsorbed may not be effectively removed by the cleaning composition.

In an example embodiment, the cleaning composition may further include water. The water may occupy a remainder of the cleaning composition except for the inorganic acid or salt thereof and the organic acid. In an example embodiment, the water may be deionized water.

A cleaning composition according to an example embodiment includes an inorganic acid or salt thereof and an organic acid, wherein the organic acid has a first acid dissociation constant (PKa₁) and a second acid dissociation constant, and the value of the first acid dissociation constant is less than the value of the second acid dissociation constant. The value of the first acid dissociation constant may be about 1 to about 3, and the value of the second acid dissociation constant may be about 4 to about 7.

The inorganic acid or salt thereof may combine with tin formed on the EUV mask by performing a lithography process to make the tin soluble in water. Therefore, the tin may be effectively removed from the EUV mask by combining with the inorganic acid or the salt thereof and then dissolving in water.

The organic acid may chelate with tin oxide formed, for example, on the EUV mask through a lithography process to form a chelate compound with tin of the tin oxide. Therefore, tin of the tin oxide may be effectively removed from the EUV mask by forming a chelate compound with the organic acid.

In addition, unlike existing cleaning methods for removing tin from a EUV mask, the cleaning method using the cleaning composition according to an example embodiment may include removing tin and tin oxide formed on the EUV mask through wet cleaning using the cleaning composition. Therefore, removal of, for example, tin and/or tin oxide from a EUV mask pattern, which is limited due to the difficulties of SEM analysis in the existing cleaning methods based on SEM analysis, may be effectively performed, and the EUV mask may be cleaned quickly compared to previously existing cleaning methods, so that the structural and functional integrity of the EUV mask may be ensured.

A cleaning composition according to an example embodiment may be used to clean a EUV mask used, for example, in a lithography process using EUV light. In addition, the cleaning composition according to an example embodiment may be used to clean an inorganic photoresist composition remaining on a substrate after, for example, a lithography process using EUV light is performed.

Hereinafter, the configuration and effects of some example embodiments of inventive concepts are described in more detail with specific examples and comparative examples, but these examples and comparative examples are only intended to more clearly understand some example embodiments of the inventive concepts, and are not intended to limit the scope of the inventive concepts.

Table 1 shows results of measuring etch rates of a tin film, a tin oxide film, a ruthenium film, a tantalum film, and a silicon oxide film according to the inorganic acid or salt thereof content, the organic acid content, and the water content of the cleaning composition according to an Example.

Table 2 shows results of measuring etch rates of the tin film, the tin oxide film, the ruthenium film, the tantalum film, and the silicon oxide film according to the inorganic acid or salt thereof content, the organic acid content, and the water content of the cleaning composition according to a Comparative Example.

In Tables 1 and 2, the etch rate of the tin film is prepared by cutting a silicon wafer having a tin film having a thickness of about 10000 Å on the upper surface into a size of about 2 cm×about 2 cm, preparing a specimen, diluting the prepared specimen in the cleaning compositions of the Example and the Comparative Example at a temperature of about 60° C. for about 10 seconds, cleaning the diluted specimen with water, then drying the specimen with nitrogen gas (N₂), and then measuring a thickness of the tin film of the specimen before and after immersion through X-ray fluorescence spectroscopy (XRF). In Tables 1 and 2, ⊚ means that the etch rate of the tin film is 20000 Å/min or more, ∘ means that the etch rate of the tin film is 18000 Å/min or more and less than 20000 Å/min, and Δ means that the etch rate of the tin film is 16000 Å/min or more and less than 18000 Å/min, and x means that the etch rate of the tin film is less than 16000 Å/min.

In Tables 1 and 2, the etch rate of the tin oxide film is prepared by cutting a silicon wafer having a tin oxide film having a thickness of about 1000 Å on the upper surface into a size of about 2 cm×about 2 cm, preparing a specimen, diluting the prepared specimen in the cleaning compositions of the Example and the Comparative Example at a temperature of about 60° C. for about 10 seconds, cleaning the diluted specimen with water, then drying the specimen with N₂, and then measuring a thickness of the tin oxide film of the specimen before and after immersion through XRF. In Tables 1 and 2, ⊚ means that the etch rate of the tin oxide film is 10 Å/min or more, ∘ means that the etch rate of the tin oxide film is 7 Å/min or more and less than 10 Å/min, and Δ means that the etch rate of the tin oxide film is 3 Å/min or more and less than 7 Å/min, and x means that the etch rate of the tin oxide film is less than 3 Å/min.

In Tables 1 and 2, the etch rate of the ruthenium film is prepared by cutting a silicon wafer having a ruthenium film having a thickness of about 300 Å on the upper surface into a size of about 2 cm×about 2 cm, preparing a specimen, diluting the prepared specimen in the cleaning compositions of the Example and the Comparative Example at a temperature of about 60° C. for about 10 minutes, cleaning the diluted specimen with water, then drying the specimen with N₂, and then measuring a thickness of the ruthenium film of the specimen before and after immersion through XRF. In Tables 1 and 2, ⊚ means that the etch rate of the ruthenium film is less than 1 Å/min, ∘ means that the etch rate of the ruthenium film is 1 Å/min or more and less than 3 Å/min, and Δ means that the etch rate of the ruthenium film is 3 Å/min or more and less than 5 Å/min, and x means that the etch rate of the ruthenium film is 5 Å/min or more.

In Tables 1 and 2, the etch rate of the tantalum film is prepared by cutting a silicon wafer having a tantalum film having a thickness of about 20 Å on the upper surface into a size of about 2 cm×about 2 cm, preparing a specimen, diluting the prepared specimen in the cleaning compositions of the Example and the Comparative Example at a temperature of about 60° C. for about 6 hours, cleaning the diluted specimen with water, then drying the specimen with N₂, and then measuring a thickness of the tantalum film of the specimen before and after immersion through XRF. In Tables 1 and 2, ⊚ means that the etch rate of the tantalum film is less than 1 Å/min, ∘ means that the etch rate of the tantalum film is 1 Å/min or more and less than 3 Å/min, and Δ means that the etch rate of the tantalum film is 3 Å/min or more and less than 5 Å/min, and x means that the etch rate of the tantalum film is 5 A/min or more.

In Tables 1 and 2, the etch rate of the silicon oxide film may be obtained by preparing a specimen by cutting a silicon oxide wafer into a size of about 1.5 cm×about 1.5 cm, and diluting the prepared specimen with dilute hydrofluoric acid (DHF) diluted to about 200:1, measuring a thickness of the specimen diluted with the DHF by using an ellipsometer, diluting the specimen in the cleaning compositions of the Example and the Comparative Example at a temperature of about 60° C. for about 2 minutes, cleaning the specimen with ultrapure water and drying the specimen with air, then measuring a thickness of the specimen dried with the ellipsometer, and comparing the thickness of the specimen measured after being diluted in the DHF to the thickness of the specimen measured after being dried. In Tables 1 and 2, @ means that the etch rate of the silicon oxide film is less than 1 Å/min, ∘ means that the etch rate of the silicon oxide film is 1 Å/min or more and less than 3 Å/min, and Δ means that the etch rate of the silicon oxide film is 3 A/min or more and less than 5 Å/min, and x means that the etch rate of the silicon oxide film is 5 Å/min or more.

TABLE 1

| | A-1 | A-2 | A-3 | B-1 | B-2 | B-3 | C-1 | D-1 | D-2 | D-3 | DIW | Sn | SnO₂ | Ru | Ta | SiO₂ |
|---|---|---|---|---|---|---|---|---|---|---|---|---|---|---|---|---|
| Example 1 | 3 | | | | 0.5 | | | | | | 96.5 | ◯ | ⊚ | ⊚ | ⊚ | ⊚ |
| Example 2 | 3 | | | | 3 | | | | | | 94 | ◯ | ◯ | ◯ | ◯ | ⊚ |
| Example 3 | 5 | | | | 0.5 | | | | | | 94.5 | ⊚ | ⊚ | ⊚ | ⊚ | ⊚ |
| Example 4 | 5 | | | | 1 | | | | | | 94 | ◯ | ⊚ | ◯ | ⊚ | ⊚ |
| Example 5 | 10 | | | | 0.5 | | | | | | 89.5 | ⊚ | ⊚ | ⊚ | ⊚ | ⊚ |
| Example 6 | 20 | | | | 0.5 | | | | | | 79.5 | ⊚ | ⊚ | ⊚ | ⊚ | ⊚ |
| Example 7 | 30 | | | | 0.5 | | | | | | 69.5 | ⊚ | ◯ | ⊚ | ⊚ | ⊚ |
| Example 8 | 0.5 | | | | 0.5 | | | | | | 99 | Δ | ◯ | ◯ | ⊚ | ⊚ |
| Example 9 | 1 | | | | 0.5 | | | | | | 98.5 | Δ | ⊚ | ⊚ | ⊚ | ⊚ |
| Example 10 | 35 | | | | 0.5 | | | | | | 64.5 | ◯ | Δ | ⊚ | ⊚ | ⊚ |
| Example 11 | | 3 | | 0.5 | | | | | | | 96.5 | ◯ | ⊚ | ⊚ | ⊚ | ⊚ |
| Example 12 | | 5 | | 0.5 | | | | | | | 94.5 | ⊚ | ⊚ | ⊚ | ⊚ | ⊚ |
| Example 13 | | 7 | | 0.5 | | | | | | | 92.5 | ⊚ | ⊚ | ⊚ | ⊚ | ⊚ |
| Example 14 | | 20 | | 0.5 | | | | | | | 79.5 | ⊚ | ⊚ | ⊚ | ⊚ | ⊚ |
| Example 15 | | 30 | | 0.5 | | | | | | | 69.5 | ◯ | ⊚ | ⊚ | ⊚ | ⊚ |
| Example 16 | | 10 | | 0.01 | | | | | | | 89.99 | ⊚ | Δ | ⊚ | ⊚ | ⊚ |
| Example 17 | | 10 | | 0.1 | | | | | | | 89.9 | ⊚ | ⊚ | ⊚ | ⊚ | ⊚ |
| Example 18 | | 10 | | 0.7 | | | | | | | 89.3 | ⊚ | ⊚ | ⊚ | ⊚ | ⊚ |
| Example 19 | | 10 | | 1 | | | | | | | 89 | ⊚ | ⊚ | ⊚ | ⊚ | ⊚ |
| Example 20 | | 10 | | 1.5 | | | | | | | 88.5 | ◯ | ⊚ | ⊚ | ⊚ | ⊚ |
| Example 21 | 10 | | | | 0.5 | | | | | | 89.5 | ⊚ | ⊚ | ⊚ | ⊚ | ⊚ |
| Example 22 | | 10 | | 0.5 | | | | | | | 89.5 | ⊚ | ⊚ | ⊚ | ⊚ | ⊚ |
| Example 23 | | | 10 | 0.5 | | | | | | | 89.5 | ⊚ | ⊚ | ⊚ | ⊚ | ⊚ |
| Example 24 | 10 | | | | | 0.5 | | | | | 89.5 | ⊚ | ◯ | ⊚ | ⊚ | ⊚ |
| Example 25 | | 10 | | | | 0.5 | | | | | 89.5 | ⊚ | ◯ | ⊚ | ⊚ | ⊚ |
| Example 26 | | | 10 | | | 0.5 | | | | | 89.5 | ⊚ | ◯ | ⊚ | ◯ | ⊚ |
| Example 27 | | 10 | | | 0.5 | | 0.1 | | | | 89.4 | ⊚ | ⊚ | Δ | Δ | Δ |
| Example 28 | | 10 | | | 0.5 | | | 0.1 | | | 89.4 | ⊚ | ⊚ | Δ | Δ | ⊚ |
| Example 29 | | 10 | | | 0.5 | | | | 0.1 | | 89.4 | Δ | ◯ | ◯ | ◯ | ⊚ |
| Example 30 | | 10 | | | 0.5 | | | | | 0.1 | 89.4 | ◯ | ◯ | Δ | ◯ | ⊚ |

TABLE 2

| | A-2 | B-1 | B-2 | B-3 | B-4 | B-5 | B-6 | B-7 | C-1 | C-2 | C-3 | D-1 | DIW | Sn | SnO₂ | Ru | Ta | SiO₂ |
|---|---|---|---|---|---|---|---|---|---|---|---|---|---|---|---|---|---|---|
| Comparative | 10 | | | | | | | | | | | | 90 | ⊚ | X | ⊚ | ⊚ | ⊚ |
| Example 1 | | | | | | | | | | | | | | | | | | |
| Comparative | | 0.5 | | | | | | | | | | | 99.5 | X | ◯ | ⊚ | ⊚ | ⊚ |
| Example 2 | | | | | | | | | | | | | | | | | | |
| Comparative | | | 0.5 | | | | | | | | | | 99.5 | X | ◯ | ⊚ | ⊚ | ⊚ |
| Example 3 | | | | | | | | | | | | | | | | | | |
| Comparative | | | | 0.5 | | | | | | | | | 99.5 | X | ⊚ | ⊚ | ⊚ | ⊚ |
| Example 4 | | | | | | | | | | | | | | | | | | |
| Comparative | 10 | | | | 0.5 | | | | | | | | 89.5 | ◯ | X | ⊚ | ⊚ | ⊚ |
| Example 5 | | | | | | | | | | | | | | | | | | |
| Comparative | 10 | | | | | 0.5 | | | | | | | 89.5 | ◯ | X | ⊚ | ⊚ | ⊚ |
| Example 6 | | | | | | | | | | | | | | | | | | |
| Comparative | 10 | | | | | | 0.5 | | | | | | 89.5 | ◯ | X | ⊚ | ⊚ | ⊚ |
| Example 7 | | | | | | | | | | | | | | | | | | |
| Comparative | 10 | | | | | | | 0.5 | | | | | 89.5 | Δ | X | ⊚ | ⊚ | ⊚ |
| Example 8 | | | | | | | | | | | | | | | | | | |
| Comparative | | | 0.5 | | | | | | 10 | | | | 89.5 | X | Δ | Δ | Δ | X |
| Example 9 | | | | | | | | | | | | | | | | | | |
| Comparative | | | 0.5 | | | | | | | 10 | | | 89.5 | X | Δ | Δ | ⊚ | ⊚ |
| Example 10 | | | | | | | | | | | | | | | | | | |
| Comparative | | | 0.5 | | | | | | | | 10 | | 89.5 | X | Δ | ⊚ | ⊚ | ⊚ |
| Example 11 | | | | | | | | | | | | | | | | | | |
| Comparative | | | 0.5 | | | | | | | | | 10 | 89.5 | X | ◯ | Δ | Δ | ⊚ |
| Example 12 | | | | | | | | | | | | | | | | | | |

In Tables 1 and 2, A-1 means ammonium nitrate, A-2 means nitric acid, A-3 means sulfuric acid, B-1 means oxalic acid, B-2 means maleic acid, B-3 means malonic acid, B-4 means succinic acid, B-5 means acetic acid, B-6 means formic acid, B-7 means ammonium oxalate, C-1 means hydrofluoric acid, C-2 means hydrochloric acid, C-3 means phosphoric acid, D-1 means hydrogen peroxide, D-2 means tetramethyl ammonium hydroxide (TMAH), and D-3 means trimethylglycine.

Comparing Example 21 with Comparative Example 1, it can be identified that in Example 21, tin oxide is well-cleaned, but in Comparative Example 1, tin oxide is not well-cleaned. The difference between Example 21 and Comparative Example 1 is whether or not maleic acid (an example of an organic acid) is included, and it may be identified that whether or not the organic acid is included in the cleaning composition has a great effect on the removal of tin oxide.

Comparing Example 25 with Comparative Example 4, it can be identified that in Example 25, tin is well-cleaned, but in Comparative Example 4, tin is not well-cleaned. The difference between Example 25 and Comparative Example 4 is whether or not nitric acid (an example of an inorganic acid or salt thereof) is included, and it may be identified that whether or not the inorganic acid or salt thereof is included in the cleaning composition has a great effect on removal of tin.

Comparing Example 22 with Comparative Examples 5 to 8, it may be identified that in Example 22, tin oxide is well-cleaned, but in Comparative Examples 5 to 8, tin oxide is not cleaned well. The difference between Example 22 with Comparative Examples 5 to 8 is that whether the first acid dissociation constant (Pka₁) value of the organic acid included in the cleaning composition is from about 1 to about 3, and whether the second acid dissociation constant (Pka₂) value is from about 4 to about 7, and accordingly, when the organic acid included in the cleaning composition has a first acid dissociation constant (Pka₁) value of about 1 to about 3 and a second acid dissociation constant (Pka₂) value of about 4 to about 7, it may be identified that tin oxide is may be effectively cleaned.

Looking at Comparative Examples 9 and 10, it may be identified that in Comparative Example 9, the ruthenium film, the tantalum film, and the silicon oxide film are removed, and in Comparative Example 10, the ruthenium film is removed. Through this, it may be identified that hydrofluoric acid included in Comparative Example 9 removes unwanted ruthenium film, tantalum film, and silicon oxide film, and that hydrochloric acid included in Comparative Example 10 causes removal of an unwanted ruthenium film.

Comparing Comparative Example 3 with Comparative Example 11, it may be identified that, in the case of Comparative Example 3, removal of tin oxide is effectively performed by including maleic acid, which is an organic acid having a first acid dissociation constant (Pka₁) value of about 1 to about 3 and a second acid dissociation constant (Pka₂) value of about 4 to about 7, but in the case of Comparative Example 11, removal of tin oxide is not effectively performed even though maleic acid, which is the same organic acid as in Comparative Example 3, is included. Because the difference between Comparative Example 3 and Comparative Example 11 is whether or not phosphoric acid is included in the cleaning composition, it may be identified that phosphoric acid interferes with the removal of tin oxide through organic acid.

Comparing Comparative Example 3 with Comparative Example 12, it may be identified that, in the case of Comparative Example 3, the ruthenium film and the tantalum film are not well removed, but in the case of Comparative Example 12, the ruthenium film and the tantalum film are relatively well removed. Because the difference between Comparative Example 3 and Comparative Example 12 is whether or not hydrogen peroxide is included in the cleaning composition, it may be identified that hydrogen peroxide removes an unwanted ruthenium film and an unwanted tantalum film.

Comparing Examples 12 to 14 with Examples 11 and 15, it may be identified that, in Examples 12 to 14, tin cleaning is effectively performed, but in Examples 11 and 15, tin cleaning is performed relatively poorly. Because the difference between Examples 12 to 14 and Examples 11 and 15 is the difference in the content of nitric acid (, an example of inorganic acid or salt thereof) included in the cleaning composition, when the content of the inorganic acid or salt thereof is 5 wt % to 20 wt % based on the total weight of the cleaning composition, it may be identified that the removal of tin is performed more effectively.

Comparing Examples 17 to 19 with Example 16, it may be identified that, in Examples 17 to 19, cleaning for tin oxide is effectively performed, but in Example 16, removal of tin oxide is relatively poorly performed. Because the difference between Examples 17 to 19 and Example 16 is the difference in the content of oxalic acid (an example of an organic acid) included in the cleaning composition, when the organic acid content is 0.1 wt % to 1 wt % based on the total weight of the cleaning composition, it may be identified that removal of tin oxide is performed more effectively.

Comparing Examples 3 and 5 with Examples 8 and 10, it may be identified that, in Examples 3 and 5, removal of tin and tin oxide is effectively performed, but in Examples 8 and 10, removal of tin and tin oxide is performed relatively poorly, and in Example 8, an unwanted ruthenium film is removed. Because the difference between Examples 3 and 5 and Examples 8 and 10 is that the ratio of the content of the organic acid to the content of the inorganic acid in the cleaning composition, when the ratio of the content of the organic acid to the content of the inorganic acid is about 1:5 to about 1:20, it may be identified that removal of tin and/or tin oxide is performed more effectively, and when the organic acid content is too high, an unwanted ruthenium film is removed.

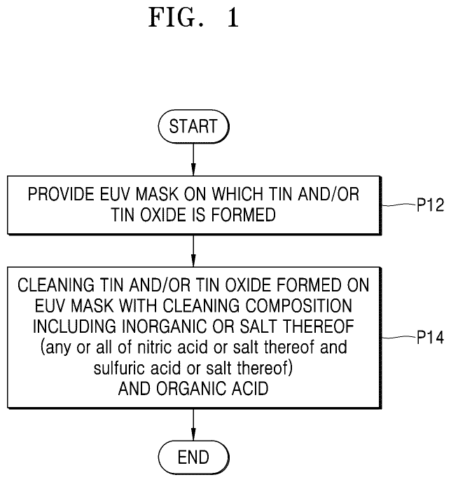

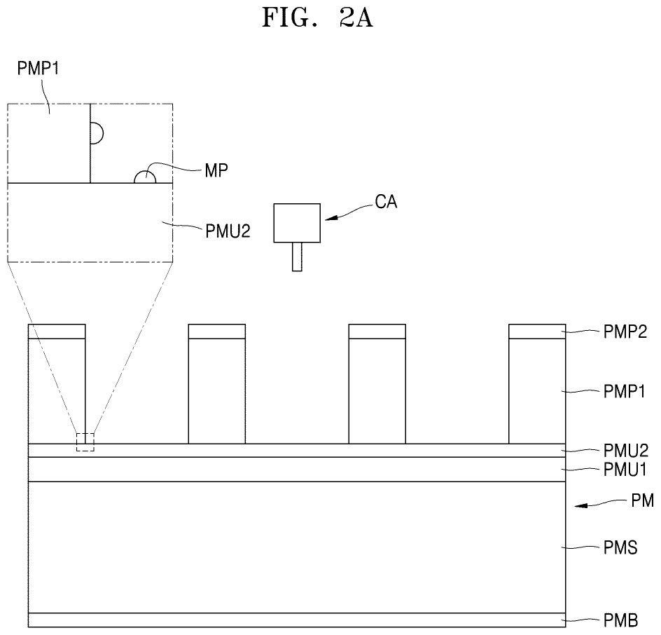

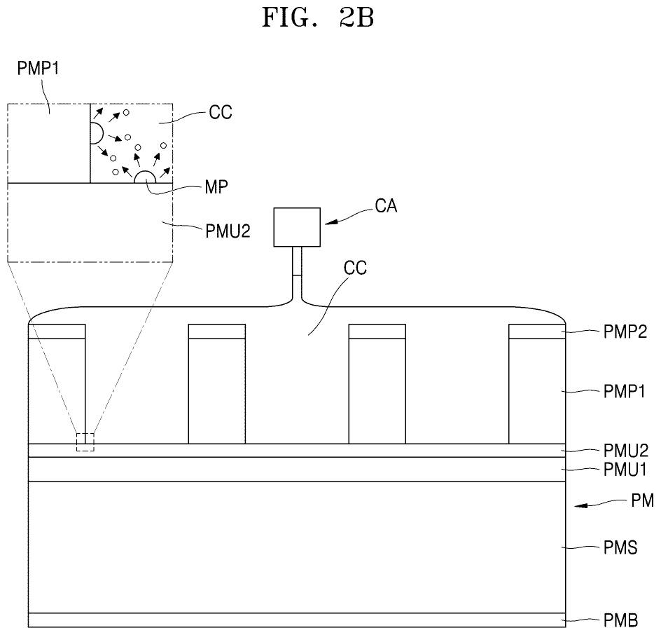

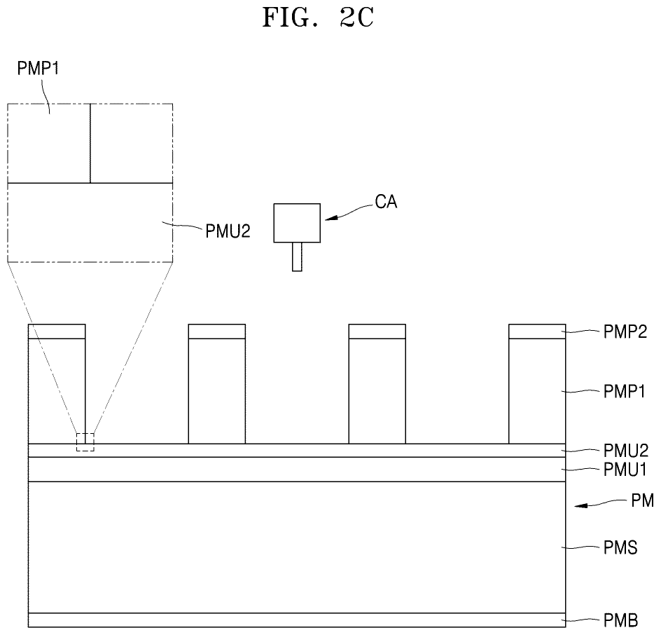

Hereinafter, a method of cleaning a EUV mask PM by using a cleaning composition, according to an example embodiment is described with reference to FIGS. 1 and 2A to 2C.

FIG. 1 is a flowchart of a method of cleaning a mask, according to an example embodiment. FIGS. 2A to 2C are cross-sectional views illustrating steps of a method of cleaning a mask, according to some example embodiments.

Referring to FIGS. 1 and 2A, a EUV mask PM used in a lithography process using EUV light may be provided in operation P12. The EUV mask PM may include a mask substrate PMS, a backside conductive film PMB arranged on a lower surface of the mask substrate PMS, a reflective layer PMU1 and a capping layer PMU2, which are sequentially arranged on an upper surface of the mask substrate PMS, and an absorption layer PMP1 arranged on the capping layer MU2, and a low reflective layer PMP2 arranged on the absorption layer PMP1.

The mask substrate PMS may include, for example, a dielectric, glass, semiconductor, or metal material. For example, the mask substrate PMS may include low thermal expansion material (LTEM) glass, such as synthetic quartz glass, quartz glass, aluminosilicate glass, soda lime glass, and SiO₂—TiO₂-based glass, or crystallized glass provided by precipitating a β quartz solid solution, single crystal silicon, silicon carbide (SiC), or any combination thereof.

The reflective layer PMU1 may include a plurality of layers. For example, the reflective layer PMU1 may have a stack structure in which a layer having a high refractive index and a layer having a low refractive index are alternately stacked. For example, the reflective layer PMU1 may include a stack structure in which, for example, Mo/Si, Ru/Si, Be/Mo, Si/Nb, Si/Mo/Ru, Si/Mo/Ru/Mo, or Si/Ru/Mo/Ru are alternately stacked.

The capping layer PMU2 may protect the reflective layer PMU1 in a process of patterning the EUV mask PM and prevent a surface of the reflective layer PMU from being oxidized. The capping layer PMU2 may include a metal material. For example, the capping layer PMU2 may include Ru, Ni, Ir, or any of alloys thereof.

The absorption layer PMP1 may include a material having low reflectance of EUV light. For example, the absorption layer PMP1 may include a material having a maximum reflectance of about 5% or less for EUV light. For example, the absorption layer PMP1 may include TaO, TaN, TaHf, TaHfN, TaBSi, TaBSiN, TaB, TaBN, TaSi, TaSiN, TaGe, TaGEN, TaZr, TaZrN, or any combinations thereof.

During inspection of the EUV mask PM, the low reflective layer PMP2 may provide a relatively low reflectance to inspection light to obtain sufficient contrast. The low reflective layer PMP2 may include, for example, TaBO, TaBNO, TaOH, TaON, or TaONH.

The backside conductive layer PMB may be used to support the mask substrate PMS through an electrostatic chuck. The backside conductive layer PMB may include, for example, TaB.

Tin contaminants MP may be formed on a surface of the EUV mask PM used in a lithography process using EUV light. The tin contaminants MP may be, for example, tin and/or tin oxide. When the tin contaminants MP is not removed from but remains on the EUV mask PM, a defect may occur in a lithography process using the EUV mask PM in which the tin contaminant MP remains.

Referring to FIGS. 1, 2B, and 2C, the tin contaminant MP formed on the EUV mask PM may be cleaned by using a cleaning composition CC, in operation P14.

The cleaning composition CC may be supplied to the EUV mask PM by a cleaning composition supply device CA. The cleaning composition CC may include an inorganic acid or salt thereof and an organic acid, which are elements of the cleaning composition according to the example embodiment described above. A more detailed configuration of the cleaning composition is as described above.

In the P14 process, the tin contaminants MP formed on the EUV mask PM may be removed from the EUV mask PM by the cleaning composition CC. For example, when the tin contaminant is tin, the inorganic acid or salt thereof included in the cleaning composition CC combines with tin to make the tin soluble in water. Therefore, tin combined with an inorganic acid or salt thereof may be dissolved in water and removed from the EUV mask PM. In addition, for example, when the tin contaminant is tin oxide, the organic acid included in the cleaning composition CC provides hydrogen ions, and the hydrogen ions chelate with the tin oxide to form a chelate compound with tin of the tin oxide. The chelate compound may be removed from the EUV mask PM.

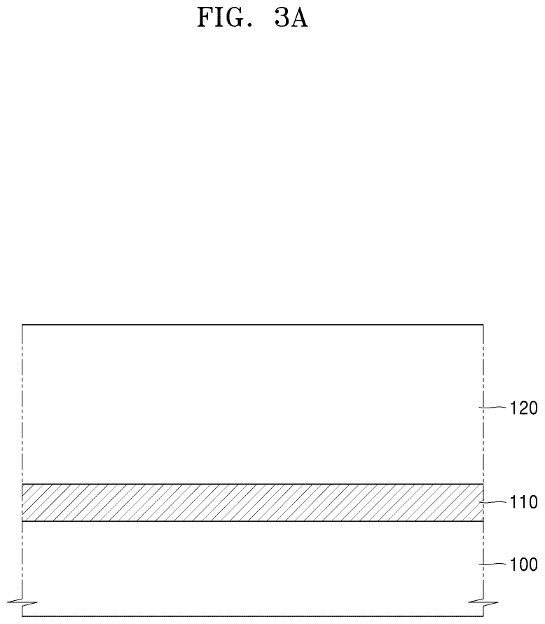

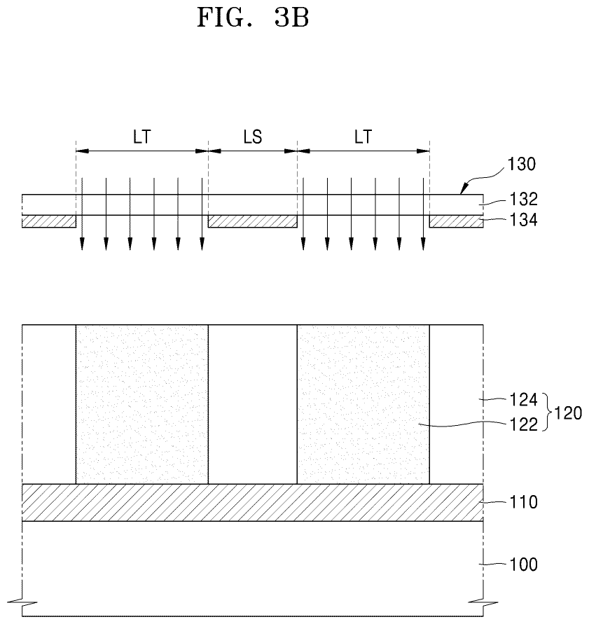

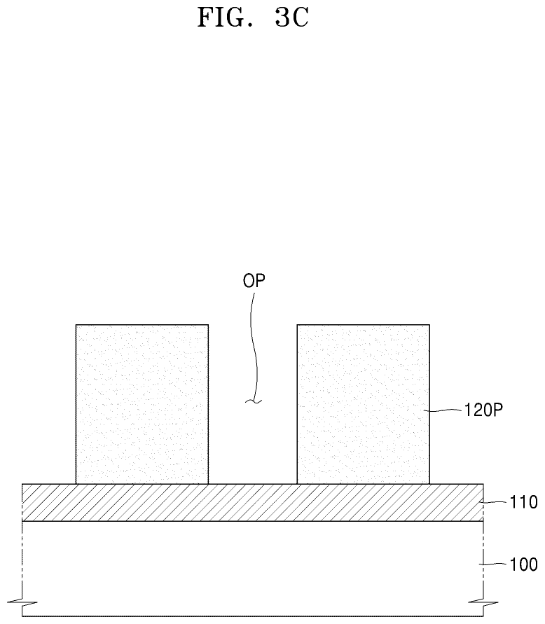

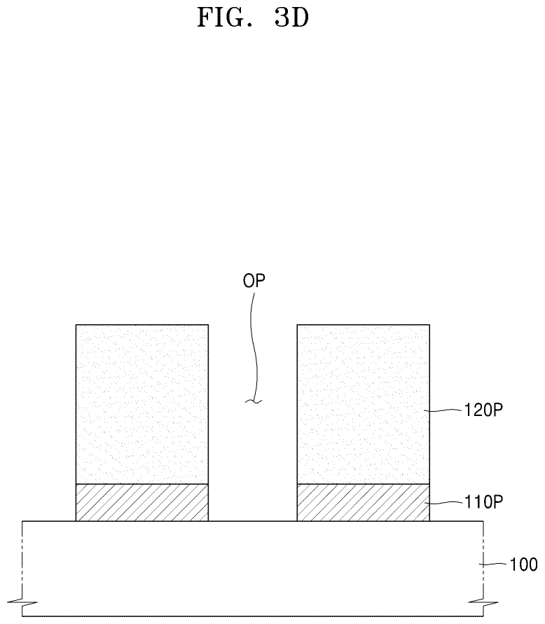

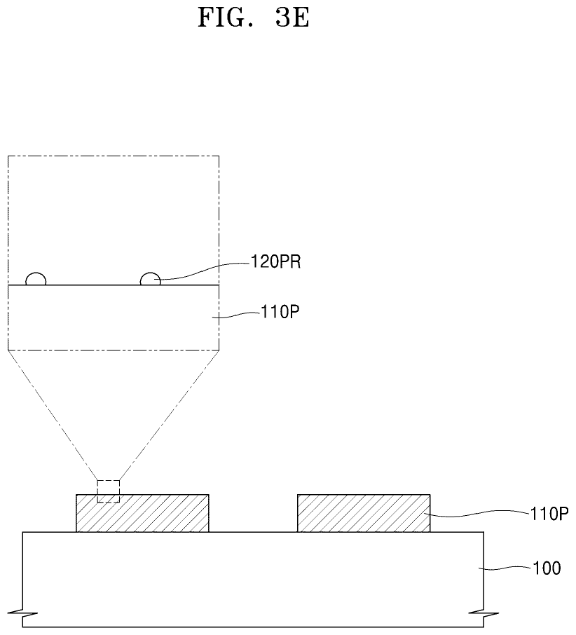

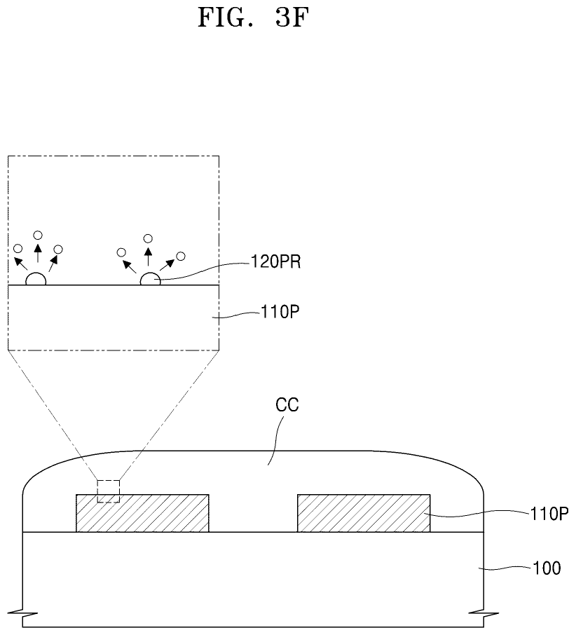

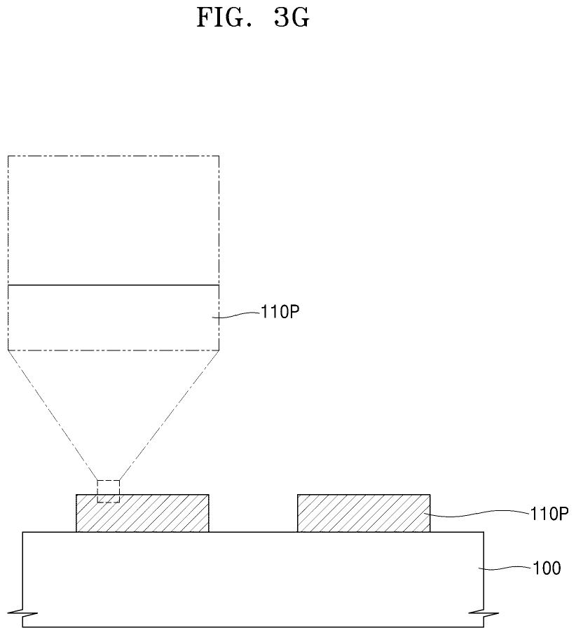

FIGS. 3A to 3G are cross-sectional views illustrating each step of a method of cleaning a substrate, according to an example embodiment.

Referring to FIG. 3A, a feature layer 110 may be formed on a substrate 100 and a photoresist layer 120 may be formed on the feature layer 110.

In an example embodiment, the photoresist layer 120 may include an inorganic photoresist composition including tin used in a EUV lithography process.

The substrate 100 may include a semiconductor substrate. For example, the substrate 100 may include a semiconductor material, such as silicon (Si) or germanium (Ge), or a compound semiconductor material, such as SiGe, SiC, GaAs, InAs, or InP. The feature layer 110 may be an insulating layer, a conductive layer, or a semiconductor layer. For example, the feature layer 110 may include a metal, an alloy, metal carbide, metal nitride, metal oxynitride, metal oxycarbide, semiconductor, polysilicon, oxide, nitride, oxynitride, or any combinations thereof, but example embodiments are not limited thereto

To form the photoresist layer 120, a photoresist composition may be coated on the feature layer 110. The coating may be performed by a method such as spin coating, spray coating, or dip coating. The photoresist layer 120 may be formed to a thickness of about 10 nm to about 1 μm, but example embodiments are not limited thereto.

In an example embodiment, the photoresist composition may be heat treated. The process of heat treating the photoresist composition may be performed at a temperature of about 60° C. to about 300° C. for about 10 seconds to about 100 seconds, but example embodiments are not limited thereto.

Referring to FIG. 3B, a first area 122, which is a portion of the photoresist layer 120, may be exposed.

In some example embodiments, to expose the first area 122 of the photoresist layer 120, a photomask 130 having a plurality of light shielding areas LS and a plurality of light transmitting areas LT may be aligned at a position on the photoresist layer 120, and the first area 122 of the photoresist layer 120 may be exposed through the plurality of light-transmitting areas LT of the photomask 130. To expose the first area 122 of the photoresist layer 120, a KrF excimer laser (248 nm), an ArF excimer laser (193 nm), an F2 excimer laser (157 nm), a EUV laser (13.5 nm), or an electron beam may be used. In some example embodiments, a reflective photomask may be used instead of a transmissive photomask according to a type of light source. Hereinafter, a description is given focusing on a transmissive photomask, but a person ordinarily skilled in the art would understand that exposure may be performed by an equivalent configuration for a reflective photomask.

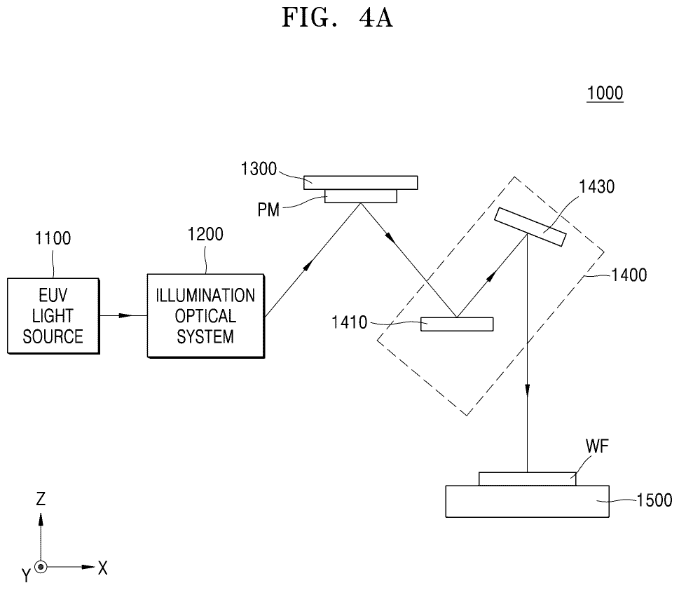

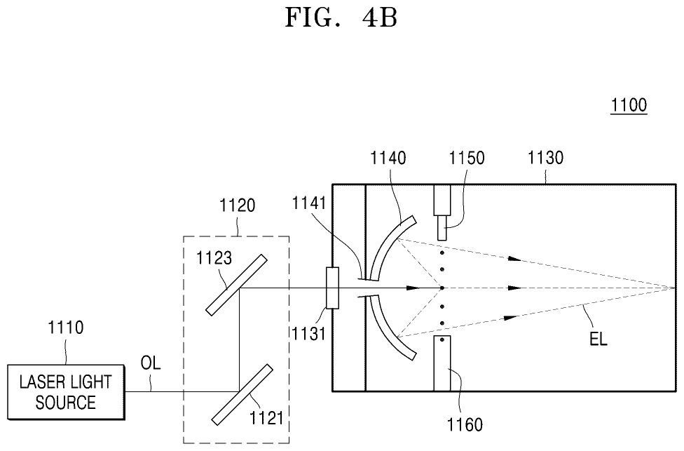

The photomask 130 may include, for example, a transparent substrate 132 and a plurality of light shielding patterns 134 formed in the plurality of light shielding areas LS on a transparent substrate 132. The transparent substrate 132 may include, for example, quartz. The plurality of light shielding patterns 134 may include chromium (Cr). The plurality of light transmitting areas LT may be defined by the plurality of light shielding patterns 134. In an example embodiment, a reflective photomask (not shown) for EUV exposure may be used instead of the photomask 130 to expose the first area 122 of the photoresist layer 120. Hereinafter, EUV exposure using a reflective photomask for EUV exposure is described with reference to FIGS. 4A and 4B.

FIGS. 4A and 4B are schematic diagrams illustrating EUV exposure performed on the photoresist layer 120 on the feature layer 110.

Referring to FIGS. 4A and 4B together, a EUV exposure device 1000 may include a EUV light source 1100, an illumination optical system 1200, a photomask support 1300, a projection optical system 1400, and a substrate stage 1500.

The EUV light source 1100 may generate and output EUV light EL having a high energy density. For example, the EUV light EL radiated from the EUV light source 1100 may have a wavelength of about 4 nm to about 124 nm. In some example embodiments, the EUV light EL may have a wavelength of about 4 nm to about 20 nm, and the EUV light EL may have a wavelength of about 13.5 nm.

The EUV light source 1100 may be a plasma-based light source or a synchrotron radiation light source. Here, the plasma-based light source means a light source that produces plasma and uses light emitted by the plasma, and may include a laser produced plasma light source or a discharge produced plasma light source.

The EUV light source 1100 may include a laser light source 1110, a delivery optical system 1120, a vacuum chamber 1130, a collector mirror 1140, a droplet generator 1150, and a droplet catcher 1160.

The laser light source 1110 may be configured to output a laserOL. For example, the laser light source 1110 may output a carbon dioxide laser. The laser OL output from the laser light source 1110 may be incident to a window 1131 of the vacuum chamber 1130 through a plurality of reflective mirrors 1121 and 1123 included in the delivery optical system 1120, and introduced into the vacuum chamber 1130.

An aperture 1141 through which the laser OL may pass is formed at the center of the collector mirror 1140, and the laser OL may be introduced into the vacuum chamber 1130 through the aperture 1141 of the collector mirror 1140.

The droplet generator 1150 may be configured to generate droplets that may generate the EUV light EL by reacting with the laser OL, and to provide the droplets into the vacuum chamber 1130. The droplets may include at least one of tin (Sn), lithium (Li), and xenon (Xe), or compounds thereof. For example, the droplets may include at least one of tin (Sn), a tin compound (e.g., SnBr4, SnBr2, or SnH), and a tin alloy (e.g., Sn—Ga, Sn—In, or Sn—In—Ga).

The droplet catcher 1160 is located below the droplet generator 1150 and may be configured to catch droplets that do not react with the laser OL. The droplets provided from the droplet generator 1150 may react with the laser OL introduced into the vacuum chamber 1130 to produce EUV light EL. The collector mirror 1140 may catch and reflect the EUV light EL and emit the EUV light EL to the illumination optical system 1200 arranged outside the vacuum chamber 1130.

The illumination optical system 1200 may include a plurality of reflective mirrors and transfer the EUV light EL emitted from the EUV light source 1100 to a EUV photomask PM. For example, the EUV light EL emitted from the EUV light source 1100 may be reflected by a reflective mirror in the illumination optical system 1200 and incident on the EUV photomask PM arranged on the photomask support 1300.

The EUV photomask PM may be a reflective mask including a reflective area and a non-reflective (or intermediate reflective) area. In an example, embodiment, the EUV photomask PM may be, for example, the EUV mask PM described with reference to FIG. 2A.

The EUV photomask PM may reflect the EUV light EL incident through the illumination optical system 1200 and allows the light to be incident to the projection optical system 1400. Specifically, the EUV photomask PM may structure light incident from the illumination optical system 1200 into projection light based on a pattern shape formed by a reflective multilayer film and an absorption pattern on the mask substrate, and allows the light to be incident to the projection optical system 1400. The projection light may be structured through at least a second diffraction order due to the EUV photomask PM. The projection light is incident to the projection optical system 1400 while retaining information on the pattern shape of the EUV photomask PM, passes through the projection optical system 1400, and forms an image corresponding to the pattern shape of the EUV photomask PM on a substrate WF.

The projection optical system 1400 may include a plurality of reflective mirrors 1410 and 1430. In the drawings, two reflective mirrors 1410 and 1430 are shown in the projection optical system 1400. However, this is for convenience of description, and the projection optical system 1400 may include more than 2 reflective mirrors. For example, the projection optical system 1400 may generally include 4 to 8 reflective mirrors. However, the number of reflective mirrors included in the projection optical system 1400 is not limited thereto.

The substrate WF may be arranged on the substrate stage 1500. The substrate stage 1500 may move in a first direction (X direction) and a second direction (Y direction) on an X-Y plane, and may move in a third direction (Z direction) perpendicular to the X-Y plane. By the movement of the substrate stage 1500, the substrate WF may also move in the first direction (X direction), the second direction (Y direction), and/or the third direction (Z direction) in the same manner.

Referring back to FIG. 3B, after exposing the first area 122 of the photoresist layer 120, the photoresist layer 120 may be annealed. The annealing may be performed at a temperature of about 50° C. to about 400° C. for about 10 seconds to about 100 seconds, but example embodiments are not limited thereto.

Referring to FIG. 3C, the photoresist layer 120 may be, for example, developed by using a developer to remove the first area 122 of the photoresist layer 120. As a result, a photoresist pattern 120P including an unexposed second area 124 of the photoresist layer 120 may be formed.

The photoresist pattern 120P may include a plurality of openings OP. After the photoresist pattern 120P is formed, a portion of the feature layer 110 exposed through the plurality of openings OP may be removed to form a feature pattern 110P.

In an example embodiment, a development of the photoresist layer 120 may be performed through a positive-tone development (PTD) process. In this case, the developer may be, for example, tetramethylammonium hydroxide (TMAH), 2-propanol, toluene, or water depending on a type of photosensitive polymer included in the photoresist composition, but example embodiments are limited thereto.

Referring to FIG. 3D, the feature layer 110 is processed using the photoresist pattern 120P.

In order to process the feature layer 110, a process of etching the feature layer 110 exposed through the opening OP of the photoresist pattern 120P, a process of implanting impurity ions into the feature layer 110, and a process of forming an additional layer on the feature layer 110 through the OP, and a process of deforming a portion of the feature layer 110 through the opening OP may be performed. FIG. 3D illustrates a case in which the feature pattern 110P is formed by etching the feature layer 110 exposed through the opening OP as an example of a process of processing the feature layer 110.

In other example embodiments, the process of forming the feature layer 110 may be omitted from the process described with reference to FIG. 3A, and in this case, the substrate 100 may be processed by using the photoresist pattern 120P, instead of the process described with reference to FIG. 3D. For example, a process of etching a portion of the substrate 100 by using the photoresist pattern 120P, a process of implanting impurity ions into a partial area of the substrate 100, and a process of forming an additional layer on the substrate 100, and a process of deforming a portion of the substrate 100 through the opening OP may be performed.

Referring to FIG. 3E, the photoresist pattern 120P remaining on the feature pattern 110P in the result of FIG. 3D may be removed. An ashing and strip process may be used to remove the photoresist pattern 120P. In this case, the photoresist composition 120PR including, for example, tin contaminants may remain on the feature pattern 110P from which the photoresist pattern 120P is removed. The tin contaminants included in the photoresist composition 120PR may include, for example, tin and/or tin oxide.

Referring to FIGS. 3F and 3G, the cleaning composition CC may be provided on the substrate 100 and/or the feature pattern 110P. The cleaning composition CC may include an inorganic acid or salt thereof and an organic acid, which are elements of the cleaning composition according to the embodiment described above. A more detailed configuration of the cleaning composition is as described above.

The photoresist composition 120PR including tin contaminants MP remaining on the feature pattern 110P may be removed by the cleaning composition CC. For example, when the tin contaminant is tin, the inorganic acid or salt thereof included in the cleaning composition CC may combine with tin to make the tin soluble in water. Therefore, tin combined with the inorganic acid or salt thereof may be dissolved in water and removed from the feature pattern 110P. In addition, for example, when the tin contaminant is tin oxide, the organic acid included in the cleaning composition CC may provide hydrogen ions, the hydrogen ions chelate with the tin oxide to form a chelate compound with tin of the oxide, and the formed chelate compound may be removed from the feature pattern 110P.

While inventive concepts have been particularly shown and described with reference to some example embodiments thereof, it will be understood that various changes in form and details may be made therein without departing from the spirit and scope of the following claims.

What is claimed is:

1. A cleaning composition, comprising:
an inorganic acid or salt thereof; and
an organic acid, wherein
the organic acid has a first acid dissociation constant (PKa₁) and a second acid dissociation constant (PKa₂),
PKa₁ is less than PKa₂,
PKa₁ is from about 1 to about 3, and
PKa₂ is from about 4 to about 7.

2. The cleaning composition of claim 1, wherein the organic acid includes two or more acidic groups.

3. The cleaning composition of claim 1, wherein the organic acid includes two or more carboxylic groups.

4. The cleaning composition of claim 1, wherein the organic acid is oxalic acid, maleic acid, or malonic acid.

5. The cleaning composition of claim 1, wherein the organic acid does not include a peroxide group.

6. The cleaning composition of claim 1, wherein a content of the organic acid is about 0.01 wt % to about 1.5 wt % based on a total weight of the cleaning composition.

7. The cleaning composition of claim 1, wherein the inorganic acid or salt thereof includes at least one of nitric acid or salt thereof and sulfuric acid or salt thereof.

8. The cleaning composition of claim 1, wherein the inorganic acid does not include a halogen element.

9. The cleaning composition of claim 1, wherein a content of the inorganic acid or salt thereof is about 3 wt % to about 30 wt % based on a total weight of the cleaning composition.

10. The cleaning composition of claim 1, wherein a ratio of a content of the organic acid to a content of the inorganic acid or salt thereof is about 1:3 to about 1:60.

11. The cleaning composition of claim 1, not comprising a surfactant.

12. A cleaning composition comprising:
an inorganic acid or salt thereof;
an organic acid; and
deionized water, wherein
the organic acid has a first acid dissociation constant (Pka₁) and a second acid dissociation constant (Pka₂),
Pka₁ is less than Pka₂,
Pka₁ is about 1 to about 3,
Pka₂ is about 4 to about 7, and
the inorganic acid or salt thereof includes at least one of sulfuric acid, salt of sulfuric acid, nitric acid, or salt of nitric acid.

13. The cleaning composition of claim 12, wherein the organic acid includes two or more carboxylic groups.

14. The cleaning composition of claim 12, wherein the organic acid is oxalic acid, maleic acid, or malonic acid.

15. The cleaning composition of claim 12, wherein a content of the organic acid is about 0.01 wt % to about 1.5 wt % based on a total weight of the cleaning composition, and a content of the inorganic acid or salt thereof is about 3 wt % to about 30 wt % based on the total weight of the cleaning composition.

16. The cleaning composition of claim 12, wherein a ratio of a content of the organic acid to a content of the inorganic acid or salt thereof is about 1:2 to about 1:60.

17. The cleaning composition of claim 12, not comprising a surfactant.

18. A method of cleaning a mask, the method comprising:
providing an extreme ultraviolet (EUV) mask used in a EUV lithography process; and
at least partially removing, by using a cleaning composition, tin or tin oxide formed on the EUV mask in the EUV lithography process, wherein
the cleaning composition includes an inorganic acid or salt thereof and an organic acid,
the organic acid has a first acid dissociation constant (PKa₁) and a second acid dissociation constant (PKa₂),
PKa₁ is less than PKa₂,
PKa₁ is about 1 to about 3,
PKa₂ is about 4 to about 7,
in the cleaning, the inorganic acid or salt thereof combines with the tin and allows the tin to be soluble in water, and
in the cleaning, the organic acid chelates with the tin oxide and forms a chelate compound with tin of the tin oxide.

19. The method of claim 18, wherein the cleaning composition does not damage the EUV mask.

20. The cleaning composition of claim 18, wherein
a content of the organic acid is about 0.01 wt % to about 1.5 wt % based on a total weight of the cleaning composition,
a content of the inorganic acid or salt thereof is about 3 wt % to about 30 wt % based on the total weight of the cleaning composition, and
a ratio of the content of the organic acid to the content of the inorganic acid or salt thereof is about 1:2 to about 1:60.
